(19) United States
(12) Patent Application Publication
(10) Pub. No.: US 2026/0323787 A1
(43) Pub. Date: Oct. 15, 2026

(54) A METHOD FOR OPERATING AN INDUCTION COOKING DEVICE

(71) Applicant: ELECTROLUX APPLIANCES AKTIEBOLAG, Stockholm (SE)

(72) Inventors: Alex VIROLI, Forli (IT); Massimo NOSTRO, Forli (IT); Massimo ZANGOLI, Forli (IT); Fabio ANGELI, Forli (IT); Emanuel URGESE, Forli (IT); Giacomo CORSI, Forli (IT); Nicola SPARNACCI, Forli (IT)

(21) Appl. No.: 19/484,646

(22) PCT Filed: Apr. 26, 2024
(86) PCT No.: PCT/EP2024/061520

§ 371 Date: Nov. 14, 2025

(30) Foreign Application Priority Data
May 15, 2023 (EP) 23173445.0

(51) Int. Cl. H05B 6/06; H02M 7/06; H03K 17/567

(52) U.S. Cl. CPC H05B 6/062; H02M 7/06; H03K 17/567; H05B 2213/05

(57) ABSTRACT

Disclosed is a method for operating an induction cooking device having a DC voltage bus and an induction heating circuit that includes an indication heating coil and a first switching element, wherein an alternating current is provided a rectified, thereby providing a DC voltage to the DC voltage bus. During a normal operation mode, a direct current corresponding to said DC voltage (Udc) is selectively provided from said DC voltage bus to the induction heating coil by means of the first switching element, wherein in said normal operation mode, said first switching element is periodically switched with a first On time.

When the first switching element is in an Off state for at least one half wave period of said alternating current, a zero crossing of said alternating current is determined, and a preliminary operation mode of the induction heating circuit is initialized.

The invention is related to a method for operating an induction cooking device, wherein an alternating current is rectified, thereby providing a DC voltage to a DC voltage bus of said induction cooking device, wherein during a normal operation mode of an induction heating circuit of said induction cooking device, a direct current corresponding to said DC voltage is selectively provided from said DC voltage bus to an induction heating coil of said induction heating circuit by means of a first switching element, said first switching element having an On state passing said direct current and an Off state blocking said direct current and being switched by applying a corresponding switching signal.

An induction cooking device (e.g., an induction hob) generally is a household appliance configured to heat a vessel disposed on some top plate (a hob plate) of the induction cooking device by inducing an oscillating electromagnetic field that penetrates the vessel, thereby generating eddy currents in the vessel. The eddy currents face the resistivity of the vessel, thus generating heat. The oscillating electromagnetic is induced by an induction heating coil of the induction cooking device, where an alternating current is provided to the induction heating coil for the generation of the oscillating electromagnetic field, normally via pulse-width modulation (PWM) of a DC current obtained in turn by rectification of an AC current of the power grid. The PWM is implemented by at least one switching device, in most cases a transistor such as an insulated gate-bipolar transistor (IGBT), to which a corresponding switching signal modelling the switching cycles, is applied (in the case of an IGBT: at its Gate).

There are several possible topologies of arranging the switching devices and the induction heating coil, and possibly a capacitance (to form a resonance circuit together with the induction heating coil), e.g., a half bridge (with two switching devices), a full bridge (with two half bridges), or also a single switch, controlling a current flow from the DC voltage bus through the induction heating coil with respect to a reference potential.

While during normal operation of the induction heating device, the switching device(s) is (are) periodically switched for the PWM, while during a so-called wake-up mode, the DC voltage bus is at the normal DC voltage, but the switching device(s) is (are) off. When in this setting, an induction hob is turned on (or possibly set to abandon a standby mode) at a user interface, and a cooking vessel is placed on the hob plate, the induction cooking device generates a click sound when going from the wake-up mode into normal operation mode, as the DC voltage bus dis-charges through the switching device(s). This may not only be a one-time phenomenon, as for a low to mid heat power output, induction hobs can well be operated normally with short operation times (in the order of a second) and set into the wake-up mode again for a similar time period. Each new short operation time will then cause this click sound, which could get really annoying to a person using the induction cooking device.

It is therefore the object of the invention to present a method for operating an induction cooking device that eliminates any click sound caused from such a DC bus discharge after a longer off state of a switching device. It is furthermore the object of the invention to present an induction cooking device configured to implement such a method.

According to the invention, the first object is solved by a method for operating an induction cooking device, wherein an alternating current is provided, wherein said alternating current is rectified, thereby providing a DC voltage to a DC voltage bus of said induction cooking device, wherein during a normal operation mode of an induction heating circuit of said induction cooking device, a direct current corresponding to said DC voltage is selectively provided from said DC voltage bus to an induction heating coil of said induction heating circuit by means of a first switching element, said first switching element having an On state passing said direct current and an Off state blocking said direct current and being switched by applying a corresponding switching signal, and wherein in said normal operation mode, said first switching element is periodically switched with a first On time, the On time being the time of the first switching element in the on state during each switching period, by means of the switching signal.

The method demands that, for the first switching element being in the Off state for at least one and preferably at least two half wave periods of said alternating current, a zero crossing of said alternating current is determined, and a preliminary operation mode of the induction heating circuit is initialized in a predetermined vicinity of said zero crossing, wherein in said preliminary operation mode, said first switching element is switched a plurality of times with a second On time, the second On time being shorter than the first On time, by means of the switching signal. Embodiments of particular advantage, which may be inventive in their own right, are outlined in the depending claims and in the following description.

According to the invention, the second object is achieved by an induction cooking device, comprising a power grid connection configured to establish a connection to an AC power grid, and configured to draw an alternating current from said AC power grid, a rectifier circuit configured to rectify said alternating current drawn from said AC power grid, thereby providing a DC voltage to a DC voltage bus, an induction heating circuit comprising at least one induction heating coil and a first switching element configured to provide the DC voltage from said DC bus to said induction heating coil, said first switching element having an On state passing a direct current and an Off state blocking said direct current and being switched by applying a corresponding switching signal, a control circuit configured to provide said switching signal to a control point of said first switching element, a zero crossing detector configured to determine a zero crossing of the alternating current drawn from the AC power grid, and a control unit configured to operate the induction heating circuit in a preliminary operation mode or in an ordinary operation mode.

In said ordinary operation mode, a direct current corresponding to said DC voltage is selectively provided from said DC voltage bus to said induction heating coil by means of said first switching element, and said first switching element is periodically switched with a first On time, the On time being the time of the first switching element in the on state during each switching period, by means of the switching signal. For the first switching element being switched off for at least one and preferably at least two half wave cycles of the alternating current, the control unit is further configured to start the preliminary operation mode in a defined vicinity of a zero crossing of the alternating current determined by the zero crossing detector. In said preliminary operation mode, said first switching element is switched a plurality of times with a second On time, the second On time being shorter than the first On time, by means of the switching signal.

The induction cooking device shares the advantages of the corresponding, aforementioned method. The features, favorable embodiments and their specific assets of said method for opera ting an induction cooking device, may be directly transferred, mutatis mutandis, to the induction cooking apparatus.

The notion of an induction cooking device shall comprise any apparatus that is configured for heating a suitable vessel via an oscillating electromagnetic field induced by said induction heating coil, in particular an induction hob with a hob plate containing a plurality of heating zones, each of which having at least one induction heating coil.

The alternating current is preferably drawn from an AC power grid. In particular, the provided alternating current has a frequency corresponding to the frequency of the local AC power grid, e.g., 50 Hz or 60 Hz. The rectification in the method is preferably performed by the rectifier circuit, said rectifier circuit preferably comprising a plurality of diodes for directing a current flow. A buffer capacitor may be connected between the DC voltage bus and a reference potential, for filtering off ripple from the rectifier circuit.

The induction cooking device comprises an induction heating circuit, which in turn comprises at least one induction heating coil and the first switching device. The induction heating circuit may further comprise a resonance capacitor, forming a resonance circuit with the induction heating coil. In particular, the first switching element is configured to selectively connect the DC voltage bus to the induction coil, and/or to or to establish a direct current flow from the DC voltage bus through the induction heating coil, in particular towards ground (at a reference potential). The first switching element to this end is preferably clamped in series with the DC voltage bus and the induction heating coil to a reference potential, enabling or blocking said direct current flow through the induction heating coil towards ground (representing the reference potential), depending on the switching signal. In particular, this comprises that the switching signal can attain two logical values (logical zero and logical one), each given by a different voltage with respect to the reference potential, and that in order to select a switching state of the first switching element, the voltage corresponding to the logical value is applied to a control point of the first switching element.

Preferably, an IGBT is used as said first switching element, and the switching signal is applied to its gate, so that the voltage to be applied to the gate is either the gate voltage for the IGBT to pass a current, i.e., for its “On state”, or preferably 0 V for the IGBT to fully block the direct current, i.e., for its “Off state”. An IGBT combines the advantages of a bipolar junction transistor (BJT), in particular, a good forward behavior and a high blocking voltage, with the ones of an FET, in particular, a nearly powerfree control. However, the first switching element may also be given by a silicon carbide (SiC) MOSFET or the like.

So, depending on the voltage value of the switching signal, the first switching element is either in the On state (pass the direct current through the induction heating coil) or in the Off state (block the direct current).

Now, the induction heating circuit is configured to operate in two different operation modes:
In the normal operation mode, the first switching element is periodically switched with a first On time Ton1, i.e., the time of the first switching element being in its On state (and thus, passing direct current through the induction heating coil).
In the preliminary operation mode, the first switching element is switched repeatedly (not necessarily repetition with a constant repetition period) with a second On time Ton2 being shorter than the first On time, i.e., Ton1>Ton2, so that du ring the preliminary operation mode, the first switching element is allowing the direct current flow from the DC voltage bus through the induction heating coil for a shorter and preferably much shorter time interval (and for a smaller fraction of the overall time) than in the normal operation mode. This way, the DC voltage bus can be discharged in a “soft” way, which allows for possibly suppressing the click noise.

In order to avoid a large current flow through the first switching element at the time of its opening, i.e., when a voltage along the first switching element is just being reduced but not equal to zero, the preliminary operation mode is initialized in a predetermined vicinity of a zero crossing of the alternating current. Preferably, said vicinity of the alternating current starts at most 30% of a half wave period, most preferably 20% of a half wave period prior to the zero crossing of the alternating current, and ends preferably 15% and most preferably 10% of a half wave period of the alternating current. Rectifier circuits typically rectify “partially” the AC input signal, in the sense that, e.g., negative half wave cycles are mirrored to be positive half wave cycles (the terms half wave period and half wave cycle are used interchangeably throughout this document), such that the minima (normally) of the DC output signal correspond to the zero crossing of the AC input signal. Thus, initializing the preliminary operation mode close to and preferably exactly at the zero crossing of the alternating current, allows for avoiding a direct current peak into the first switching element at its first switching cycles. The predetermined vicinity, in particular, can be given by an interval starting before the zero crossing of the alternating current by an amount of 30%, preferably 20%, most preferably 5% of the half wave period of the alternating current. The predetermined vicinity, in particular, can be given by an interval ending after the zero crossing of the alternating current by an amount of 10%, preferably 5%, most preferably 2.5% of the half wave period of the alternating current.

To this end, the zero crossing of the alternating current is determined, preferably by means of a suitable circuit. With knowledge of the AC frequency (normally, the AC power grid frequency), for any given starting point in time (e.g., when a user wants to start a cooking operation, or when an internal routine wants to operate the induction cooking circuit), one can predict the next zero crossing of the alternating current (the next zero point and/or minimum of the rectified direct current). The notion of determining the zero crossing shall include the prediction of posterior zero crossings from an earlier-determined zero crossing.

The way described above, the induction cooking device and its corresponding operating method allow for a “soft” discharge of the DC voltage bus prior to “re-entering” the normal operation mode after a longer period of inactivity, in a way that the first switching element is not harmed.

In an embodiment, said switching signal is set to have a first voltage with respect to a reference potential in said normal operation mode, and said switching signal is to have a second voltage with respect to said reference potential in said preliminary operation mode, said second voltage being smaller than said first voltage. In the case of an IGBT as the first switching element, the first and second voltage correspond to the respective gate voltage in the normal and preliminary operation mode, respectively. This means in particular that in the preliminary operation mode, not only the On time of the first switching element is shorter compared to the normal operation mode, but also the voltage of the switching signal applied to the first switching element is lower. This leads to a further “softening” of the switching; the click noise, if still present, can be eliminated.

Here, the shorter second On time plays a crucial role: in switching elements as an IGBT, lowering the voltage of a switching or control signal normally may risk the physical integrity of the switching element, in particular, when operated this way for a longer time. However, due to the comparatively shorter second On time, these risks are drastically reduced, as the lower voltage is applied during much shorter time intervals.

In another embodiment, said preliminary operation mode is applied during a vessel recognition mode, wherein in said vessel recognition mode, a presence of a cooking vessel on top of said induction cooking device is detected by measuring a response of an electromagnetic quantity to a magnetic testing field generated by the induction heating coil via said repeated switching of the first switching element, thereby allowing a DC current flow through the induction heating coil as each switching. Normally, an induction heating device has an automatic recognition of whether a cooking vessel is placed on top of it for heating, e.g., at a heating zone of the hob plate. This automatic recognition may be repeated every few seconds. The automatic recognition often involves generating an electromagnetic testing field via an induction heating coil by means of a few switching processes of the corresponding switching element, and observing changes in this testing field or in another electromagnetic quantity as a response to the testing field. From the changes, a presence of the vessel may be inferred. The switching for the automatic recognition may then be performed in the preliminary operation mode, in order to avoid click noises.

In yet another embodiment, said preliminary operation mode is applied prior to and for an initialization of the normal operation mode for a predetermined initialization time interval, wherein during said initialization time interval, said first switching element is periodically switched with said second On time, and wherein after said initialization time interval of operation in the preliminary operation mode, the normal operation mode of the induction cooking circuit is applied. This means in particular, that the preliminary operation mode is applied when the normal operation mode shall be initialized after a longer period of inactivity of the induction heating coil.

In particular, during normal operation mode, the switching signal is generated at the first voltage by applying a control signal to a control circuit, said control circuit generating the switching signal, wherein during preliminary operation mode, a voltage lowering circuit of the control circuit activated, said voltage lowering circuit being connected to the control circuit, and the switching signal is generated at the second voltage by applying the control signal to the control circuit with the activated voltage lowering circuit. This means in particular that during normal operation, a control signal (e.g., from a microcontroller or some other control unit) is applied to a control circuit, and the switching signal is generated having the first voltage. During preliminary operation mode, the voltage lowering circuit is activated (e.g., by the microcontroller or control unit) and lowers the first voltage of the switching signal to the second voltage before it gets applied to the first switching element. In particular, said voltage lowering circuit may be connected to the control circuit in series or in parallel, and most preferably, between an output point of the control circuit and a control point of the first switching element.

In an embodiment, the second voltage is set to be between 40% and 70% of the first voltage. Preferably, the first voltage is set in a range between 12 V and 25 V, preferably in a range between 15 V and 20 V and/or the second voltage is set in a range between 6 V and 15 V, preferably in a range between 8 V and 12 V. These values are particularly useful for an IGBT as said first switching element.

In another embodiment, the second On time is set to be between 5% and 25% of the first On time. Preferably the first On time is set in a range between 5 μs and 30 μs, and/or the second On time is set in a range between 0.5 μs and 8 μs, preferably in a range between 1 μs and 3 μs. These values are of particular advantage for switching frequencies in a range between 15 kHz and 100 kHz, in particular between 20 kHz and 30 kHz, used in induction cooking devices with IGBTs.

It is of particular advantage if the initialization time interval is set to be between 1 ms and 4 ms. This way, the DC voltage bus has time enough to get discharged softly even with a very short second On time, but the initialization time interval is still substantially shorter than a half wave period of an AC power grid, thus avoiding any possible interference when the preliminary operation mode is abandoned for the normal operation mode.

In yet another embodiment, during the initialization time interval, the second On time is steadily increased from an initial value, preferably in a range between 1 μs and 8 μs, and/or between 5% and 25% of the first On time, over the initialization time interval to reach the first On time by the end of the initialization time interval. This way, the transition from the preliminary to the normal operation mode is smoothed.

Preferably, for the induction heating coil to provide a heat output power lower than the minimum heat output power achievable during the normal operation mode, a duty cycle operation of said induction heating circuit is applied, wherein in said duty cycle operation, a duty period consisting of an Off state period of the first switching element for at least one and preferably at least two half wave periods of said alternating current, a period of the preliminary operation mode of the induction heating circuit for the initialization time interval, and a subsequent normal operation mode period is periodically repeated, wherein a duty cycle of the normal operation mode period with respect to the total duration of the duty period is determined in dependence on the desired heat output power.

This means in particular that in order to reduce the heat output power from the induction heating circuit below the minimum heat output power of the normal operation mode, this normal operation mode can get “duty cycled”, i.e., being turned on and off at a low frequency (in the order of few Hz or even lower). Each time the normal operation mode is turned on, the preliminary operation mode precedes it for a corresponding initialization time interval. When the normal operation mode is turned off, the first switching device remains in the Off state.

The attributes and properties as well as the advantages of the invention which have been described above are now illustrated with help of drawings of embodiment examples. In detail,

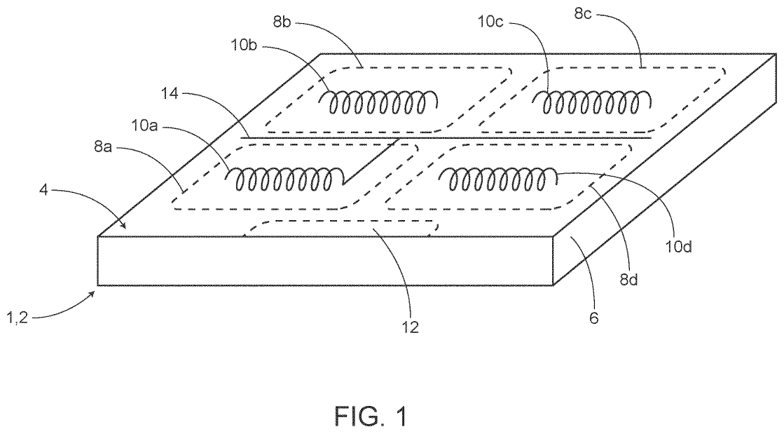

FIG. 1 shows a schematical angular view of an induction cooking device,

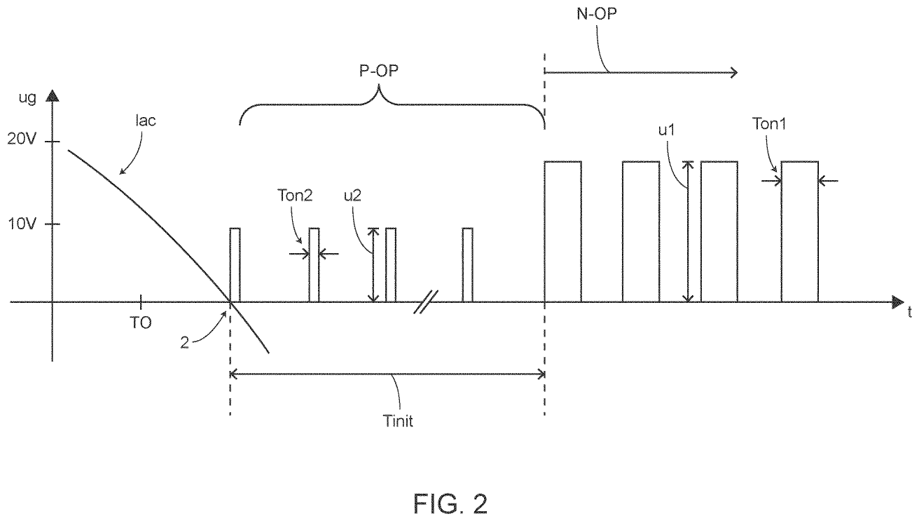

FIG. 2 shows a gate voltage of two different operation modes for an IGBT in the induction cooking device of FIG. 1, and

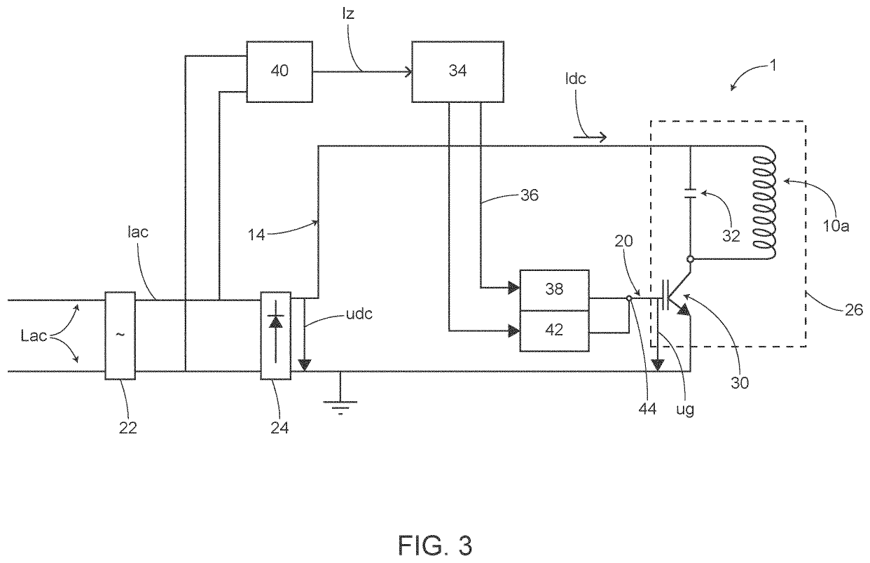

FIG. 3 shows a simplified, schematical circuit diagram of the induction cooking device of FIG. 1.

Parts and variables corresponding to one another are provided with the same reference numerals in each case of occurrence for all figures.

In FIG. 1, an induction cooking device 1 is schematically shown in an angular view. The induction cooking device 1 is given by an induction hob 2 with a hob plate 4 and a housing 6, said hob plate having four different heating zones 8a-d below each of which respective induction heating coils 10a-d are disposed in the housing 6. The hob plate can be made of glass or a ceramic material. Inside the housing 6, furthermore, means for supplying an alternating current (not shown) to each of the heating coils 10a-d are disposed.

For a typical use, the induction hob 2 is disposed in a kitchen worktop, normally the hob plate 4 being essentially level with the worktop surface. On the hob plate 4, a tactile user interface 12 is disposed for the user to select which of the four heating zones 8a-d to operate at which heating level (in arbitrary units). When the user wants to cook (or heat up) food, he places a vessel suitable for induction cooking on one of the heating zones 8a-d, say 8a, and selects the heating level via the user interface 12.

In this case, an automatic recognition of whether the vessel is indeed placed on top of the heating zone 8a may be started, said automatic recognition comprising the generation of an electromagnetic testing field via the induction heating coil 10a (by means of supplying alternating current to the induction heating coil 10a in a proper way), and furthermore the measurement of a response of an electromagnetic quantity to said electromagnetic testing field. The automatic recognition may determine whether or not the vessel is placed on top of the heating zone 8a, or may also determine whether the vessel is properly aligned with the heating zone 8a. In particular, in this automatic recognition, a current flow is established through the induction heating coil 10a after a possibly longer time of inactivity.

When recognizing the vessel to be (properly) placed on top of the heating zone 8a, the induction heating coil 10a may start the heating process by inducing electromagnetic fields which in turn induce eddy currents in the vessel, said eddy currents heating up the vessel via their resistive decay.

For the alternating current to flow through the induction heating coil 10a, the induction heating coil 10a is connected to a DC voltage bus 14 via at least one switching element (not shown in FIG. 1) in a way such that the direct current supplied by the DC voltage bus may directly flow through the induction heating coil 10a, e.g., when the switching element is open, or may have an inverse direction, e.g., by means of a resonance circuit. Via PWM, the proper alternating current flow inside the induction heating coil 10a and thus, the electromagnetic field with the desired properties may be achieved.

The range of heat output power that can be provided to a vessel, however, is limited by the PWM (and depends on the magnetic properties of the induction heating coil 10a, such as its inductivity and self-inductivity, as well as the characteristics of the switching element). Thus, with a normal PWM operation of the induction heating coil 10a, there is typically also a lower limit of the heat output power that can be supplied to a vessel. Below that lower limit, e.g., when a user wishes to only maintain food at a very moderate temperature, the PWM is normally turned on an off reiteratively (with a frequency of a few Hz or even lower), and a duty cycle of this on-off PWM being determined by the heat output power to be supplied to the vessel (depending, in turn, on the heat level selected by the user via the user interface 12).

When the switching element, normally an IGBT, is first activated after a time of inactivity, i.e., in the automatic recognition or each turn of the on-off PWM mentioned above, the DC voltage bus gets discharged, which normally will cause an unwanted clicking noise in the vessel.

In order to avoid such a clicking noise, the induction cooking device 1 of FIG. 1 is operated by a method explained with help of FIG. 2. In FIG. 2, a gate voltage Ug of a switching signal 20 that is applied to an IGBT as one of the mentioned switching elements for the respective induction heating coils 10a-d of FIG. 1, is shown as a function of time. Furthermore, an alternating current Iac of an AC power grid to which the induction cooking device 1 is connected for power supply, is also plotted (not to scale with the gate voltage Ug).

At an instant of time T0, a microcontroller (not shown in FIG. 1) sends a signal S0 to initialize the normal PWM operation of the induction heating coil 10a as explained above, be it for the automatic recognition of a vessel (only a few pulses) or for higher power heating (continuous PWM), or for a new turn of the on-off PWM mentioned above. In order to start the operation of the IGBT that switches the induction heating coil 10a, a zero crossing Iz of the alternating current Iac subsequent to the instant of time T0 is determined, and a preliminary operation mode P-Op of an induction heating circuit comprising the induction heating coil 10a and its corresponding IGBT is initialized exactly at the zero crossing Iz. The preliminary operation mode P-Op may also be initialized slightly before (e.g., 1 ms before) the zero crossing Iz.

Said zero crossing Iz may be determined, e.g., from having determined a previous zero crossing and from the knowledge of the AC power grid frequency fac, or as an alternative, the next zero crossing after the instant of time T0 may be determined, and the preliminary operation mode P-Op may start the second next zero crossing after the instant of time T0 (using the knowledge of the AC power grid frequency fac).

After an initialization time interval Tinit, the preliminary operation mode P-Op is abandoned, and the normal operation mode N-Op of the induction heating circuit comprising the induction heating coil 10a and its corresponding IGBT is started. The normal operation mode N-Op in particular corresponds to the normal, continuous PWM operation for heating. The preliminary operation mode P-Op is implemented before the normal operation mode N-Op in order to avoid the above-mentioned click noise in the cooking vessel by a “soft” discharge of the DC voltage bus 14.

During the normal operation mode N-Op, the switching signal 20 applied to the gate of the IGBT has a first voltage U1 (with respect to a reference potential), with the first voltage being U1=18V in the present example. The switching signal has non-zero contributions with a duration of a first On time Ton, traducing into a corresponding On time (pass current) of the switching element, i.e., the IGBT. The first On time Ton1 is in the order of 20 μs in the present example.

During the preliminary operation mode P-Op, the switching signal 20 applied to the gate of the IGBT has a second voltage U2 (with respect to said reference potential), with the second voltage being U2=10V in the present example. The switching signal has non-zero contributions with a duration of a second On time Ton2 in the order of 2 μs in the present example. The initialization time interval Tinit has a duration of 2 ms in the present example (not shown to scale).

In FIG. 3, a simplified schematic circuit diagram of the induction cooking device 1 of FIG. 1 is shown. The induction cooking device 1 comprises a power grid connection 22 for connecting the induction cooking device 1 to an AC power grid Lac and for obtaining an alternating current Iac from said AC power grid, a rectifier circuit 24 for rectifying said alternating current Iac, and for providing a DC voltage Udc (and a corresponding direct current Idc) to the DC voltage bus 14, an induction heating circuit 26 comprising an induction heating coil 10a and a first switching element 30 given by an IGBT, the induction heating circuit 26 preferably furthermore comprising a capacitor 32 to form a resonance circuit with the induction heating coil. The induction cooking device 1 furthermore comprises a control unit 34 configured to operate the induction heating circuit 26 in the normal operation mode N-Op or in the preliminary operation mode P-Op according to FIG. 2, in particular by sending a control signal 36 to a control circuit 38, where the switching signal 20 to be applied to the first switching element 30 is generated from the control signal 36. The control unit 34 may receive signals from the user interface 12.

The induction cooking device 1 furthermore comprises a zero crossing detector 40 for detecting a zero crossing Iz of the alternating current Iac, and a voltage lowering circuit 42 which is activated by the control unit 34 in the preliminary operation mode P-Op in order to lower the first voltage U1 of the switching signal 20 generated by the control circuit 38 to the second voltage U2. The voltage lowering circuit 42 may comprise a transistor for its activation, and a Zener diode connected to the connection point 44, for the voltage lowering.

The simplified topology shown in FIG. 3 is only one possible example, other embodiments with different topologies are possible for the implementation of the method described in FIG. 2. Even though the invention has been illustrated and described in detail with help of a preferred embodiment example, the invention is not restricted by this example. Other variations can be derived by a person skilled in the art without leaving the ex-tent of protection of this invention.

### REFERENCE NUMERAL

1 induction cooking device
2 induction hob
4 hob plate
6 housing
8a-d heating zones
10a-d induction heating coil
12 user interface
14 DC voltage bus
20 switching signal
22 power grid connection
24 rectifier circuit
26 induction heating circuit
30 first switching element
32 capacitor
34 control unit
36 control signal
38 control circuit
40 zero crossing detector
42 voltage lowering circuit
44 connection point
fac AC power grid frequency
Iac alternating current
Idc direct current
Iz zero crossing (of the alternating current)
Lac AC power grid
N-Op normal operation mode
P-Op preliminary operation mode
T0 instant of time
Tinit initialization time interval
Ton1/2 first/second On time
U1/2 first/second voltage
Ug gate voltage

1. A method for operating an induction cooking device having a DC voltage bus and an induction heating circuit that includes an indication heating coil and a first switching element,
wherein an alternating current is provided,
wherein said alternating current is rectified, thereby providing a DC voltage to the DC voltage bus,
wherein during a normal operation mode of the induction heating circuit, a direct current corresponding to said DC voltage is selectively provided from said DC voltage bus to the induction heating coil by means of the first switching element, said first switching element having an ON state passing said direct current and an OFF state blocking said direct current, said first switching element being switched by applying a corresponding switching signal,
wherein in said normal operation mode said first switching element is periodically switched with a first ON time by means of the switching signal, wherein an ON time of the first switching element is the time in which the first switching element in the ON state during each switching period,
wherein, when the first switching element is in the OFF state for at least one half wave period of said alternating current, a zero crossing of said alternating current is determined, and a preliminary operation mode of the induction heating circuit is initialized in a predetermined vicinity of said zero crossing, and
wherein in said preliminary operation mode, said first switching element is switched a plurality of times with a second ON time that is shorter than the first ON time, by means of the switching signal.

2. The method according to claim 1,
wherein in said normal operation mode, said switching signal is set to have a first voltage with respect to a reference potential, and
wherein in said preliminary operation mode, said switching signal is set to have a second voltage with respect to said reference potential, said second voltage being smaller than said first voltage.

3. The method according to claim 1,
wherein said preliminary operation mode is applied during a vessel recognition mode,
wherein in said vessel recognition mode, a presence of a cooking vessel on top of said induction cooking device is detected by measuring a response of an electromagnetic quantity to an electromagnetic testing field generated by the induction heating coil via a repeated switching of the first switching element, thereby allowing a DC current flow through the induction heating coil at each switching.

4. The method according to claim 1,
wherein said preliminary operation mode is applied prior to and for an initialization of the normal operation mode for a predetermined initialization time interval,
wherein during said initialization time interval, said first switching element periodically switched with said second ON time, and
wherein after said initialization time interval of operation in the preliminary operation mode the normal operation mode of the induction cooking circuit is applied.

5. The method according to claim 2,
wherein during the normal operation mode, the switching signal is generated at the first voltage by applying a control signal to a control circuit, said control circuit generating the switching signal, and
wherein during the preliminary operation mode, a voltage lowering circuit of the control circuit is activated, said voltage lowering circuit being connected to the control circuit, and
wherein the switching signal is generated at the second voltage by applying the control signal to the control circuit with the activated voltage lowering circuit.

6. The method according to claim 1,
wherein an insulated gate bipolar transistor is used as the first switching element,
wherein the switching signal is applied to the gate, and
wherein the first voltage and second voltage correspond to the respective gate voltage in the normal operation mode and preliminary operation mode, respectively.

7. The method according to claim 2, to wherein the second voltage is set to be between 40% and 70% of the first voltage.

8. The method according to claim 1, wherein the second ON time is set to be between 5% and 25% of the first ON time.

9. The method according to claim 1, wherein a frequency for said periodical switching of the first switching element is set between 15 kHz and 100 kHz.

10. The method according to claim 1, wherein the initialization time interval is set to be between 1 ms and 4 ms.

11. The method according to claim 1, wherein during the initialization time interval, the second ON time is steadily increased from an initial value over the initialization time interval to reach the first ON time by the end of the initialization time interval.

12. The method according to claim 1,
wherein, for the induction heating coil to provide a heat output power lower than the minimum heat output power achievable during the normal operation mode, a duty cycle operation of said induction heating circuit is applied,
wherein in said duty cycle operation, a duty period is periodically repeated, said duty period consisting of:
an OFF state period of the first switching element for at least one half wave period of said alternating current,
a period of the preliminary operation mode of the induction heating circuit for the initialization time interval, and
a subsequent normal operation mode period,
wherein a duty cycle of the normal operation mode period with respect to the total duration of the duty period is determined in dependence on a desired heat output power.

13. An induction cooking device comprising:
a power grid connection configured to establish a connection to an AC power grid, and configured to draw an alternating current from said AC power grid,
a DC voltage bus,
a rectifier circuit configured to rectify said alternating current drawn from said AC power grid, thereby providing a DC voltage to the DC voltage bus,
an induction heating circuit comprising at least one induction heating coil and a first switching element configured to provide the DC voltage from said DC voltage bus to said at least one induction heating coil, said first switching element having an ON state passing a direct current and an OFF state blocking said direct current, said first switching element being switched by applying a corresponding switching signal,
a control circuit configured to provide said switching signal to a control point of said first switching element,
a zero crossing detector configured to determine a zero crossing of the alternating current drawn from the AC power grid, and
a control unit configured to operate the induction heating circuit in a preliminary operation mode or in a normal operation mode,
wherein in said normal operation mode (N-Op), a direct current corresponding to said DC voltage is selectively provided from said DC voltage bus to said at least one induction heating coil by means of said first switching element, and said first switching element is periodically switched with a first ON time by means of the switching signal (20), wherein an ON time of the first switching element is the time of the first switching element in the ON state during each switching period,
wherein when the first switching element is switched OFF for at least one half wave cycle of the alternating current, the control unit is further configured to start the preliminary operation mode in a defined vicinity of a zero crossing of the alternating current determined by the zero crossing detector, and
wherein in said preliminary operation mode, said first switching element is switched a plurality of times with a second ON time that is shorter than the first ON time, by means of the switching signal.

14. The induction cooking device according to claim 13, further comprising a voltage lowering circuit connected to said control circuit,
wherein said control circuit is configured to provide said switching signal at a first voltage with respect to a reference potential in said normal operation mode, and
wherein said voltage lowering circuit is configured to lower the voltage of said switching signal to a second voltage with respect to said reference potential in preliminary operation mode, said second voltage being smaller than said first voltage.

15. The induction cooking device according to claim 13, wherein said first switching element is given by an insulated gate bipolar transistor.
